(19) United States
(12) Patent Application Publication
(10) Pub. No.: US 2017/0170046 A1
(43) Pub. Date: Jun. 15, 2017

(54) PIN STRUCTURE AND VACUUM APPARATUS

(71) Applicants: Shenzhen China Star Optoelectronics Technology Co., Ltd., Shenzhen, Guangdong (CN); Wuhan China Star Optoelectronics Technology Co., Ltd., Wuhan, Hubei (CN)

(72) Inventor: Yuanlong YANG, Shenzhen, Guangdong (CN)

(73) Assignees: Shenzhen China Star Optoelectronics Technology Co., Ltd., Shenzhen, Guangdong (CN); WUHAN CHINA STAR OPTOELECTRONICS TECHNOLOGY CO., LTD., Wuhan, Hubei (CN)

(21) Appl. No.: 14/905,797

(22) PCT Filed: Sep. 18, 2015
(86) PCT No.: PCT/CN2015/089993

§ 371 Date: Jan. 16, 2016

(30) Foreign Application Priority Data
Jul. 29, 2015 (CN) 201510456352.2

(51) Int. Cl. H01L 21/687

(52) U.S. Cl. CPC H01L 21/687

(57) ABSTRACT

The present invention discloses a pin structure and a vacuum apparatus, and the pin structure comprises a machine, and the machine comprises outer pins and inner pins, the outer pins are located at edges of the machine, and the inner pins are movably located in a middle area of the machine, and an amount of the inner pins is three, which are aligned with spaces corresponding to a cutting area of a glass substrate, and tops of the inner pins and the outer pins comprise metal heads; the amount of the pins is merely three to reduce the cost, and the possibility of generating electrostatic induction can be decreased in a certain level to promote the reliability of the products.

### CROSS REFERENCE

This application claims the priority of Chinese Patent Application No. 201510456352.2, entitled “PIN STRUCTURE AND VACUUM APPARATUS”, filed on Jul. 29, 2015, the disclosure of which is incorporated herein by reference in its entirety.

### FIELD OF THE INVENTION

The present invention relates to a liquid crystal display field, and more particularly to a pin structure and a vacuum apparatus.

### BACKGROUND OF THE INVENTION

In the manufacture process of the thin film transistor, the Pin structure is commonly utilized. For example, in the procedure of implementing dry etching to the glass substrate, the glass substrate has to be located in the reaction chamber for process. The pins are required to support the glass substrate. In prior art, the pins are fixed at the particular positions of the machine to correspond to the product of specific size. When it is applied for products of various sizes, the pins fixed on the machine need to be removed and then re-fix the pins on the machine according to the size of the product. The procedure is complicated and the cost is higher.

Besides, parts of the pins are located in the pixel area of the glass substrate, and the pins are made of metal material. When the pins contact the glass substrate, the electrostatic induction can easily generate. When the electrostatic discharge occurs, bad influence can be done to the product and the product quality is affected.

### SUMMARY OF THE INVENTION

An objective of the present invention is to provide a pin structure and a vacuum apparatus capable of promoting the reliability of the products.

The present invention provides a pin structure, comprising a machine, and the machine comprises outer pins and inner pins, the outer pins are located at edges of the machine, and the inner pins are movably located in a middle area of the machine, and an amount of the inner pins is three, which are aligned with spaces corresponding to a cutting area of a glass substrate, and tops of the inner pins and the outer pins comprise metal heads.

Spaces between any adjacent inner pins are equal.

Heights of the outer pins are smaller than heights of the inner pins.

A surface of the machine further comprises through holes corresponding to the inner pins to be inserted and fixed; bottoms of the inner pins comprise engaging elements, and the through holes comprise slots engaged with the engaging elements.

Heights of all the inner pins are adjustable.

Heights of the inner pins are smaller than heights of the outer pins, and the machine comprises elevating mechanisms for inserting and fixing the inner pins, and the elevating mechanisms are employed to adjust distances from the inner pins to the machine, and distances of the tops of the inner pins to the machine are larger than distances of the tops of the outer pins to the machine.

The elevating mechanisms comprise inner thread structures, and one ends of the inner pins which contact with the elevating mechanisms comprise outer thread structures, and the inner thread structures and the outer thread structures adapt, and heights of the inner pins are adjusted by rotating the inner pins.

Both the inner pins and the elevating mechanisms are cylinders, and middle parts of the elevating mechanisms comprise holes, and hole diameters of the holes are slightly larger than diameters of the inner pins, and at least two slot pairs are provided at the holes along a lateral wall direction of the elevating mechanisms, and the slot pair comprises two slots symmetrically located relative to a center of the hole, and depths of the two slots are identical, and depths of the all slot pairs are different, and outer walls of one ends of the inner pins which contact with the elevating mechanisms comprise pairs of bulges, and the pair of bulges comprises two bulges symmetrically located relative to an axis of the inner pin, and the bulges can be adapted with the slot pair.

At least two of the outer pins are distributed on four edges of the machine.

The present invention further provides a vacuum apparatus, comprising a reaction chamber, wherein the reaction chamber comprises the aforesaid pin structure, and the pin structure is employed to support the glass substrate.

The present invention discloses a pin structure and a vacuum apparatus. By locating three inner pins in the middle area of the machine, and the three inner pins correspond to the cutting area of the glass substrate, no damage occurs to the pixel structures due to the electrostatic induction even the electrostatic induction generates to ensure the quality of the product; the amount of the pins is merely three to reduce the cost, and the possibility of generating electrostatic induction can be decreased in a certain level to promote the reliability of the products.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structure diagram of one embodiment according to the pin structure of the present invention;

FIG. 2 is a sectional diagram of an inner pin and an elevating mechanism in one embodiment;

FIG. 3 is a structure diagram of an elevating mechanism in one embodiment;

FIG. 4 is a sectional diagram of an inner pin in one embodiment.

### DETAILED DESCRIPTION OF PREFERRED EMBODIMENTS

It should be noted that the specific embodiments described herein are merely for explaining the present invention and are not intended to limit the present invention.

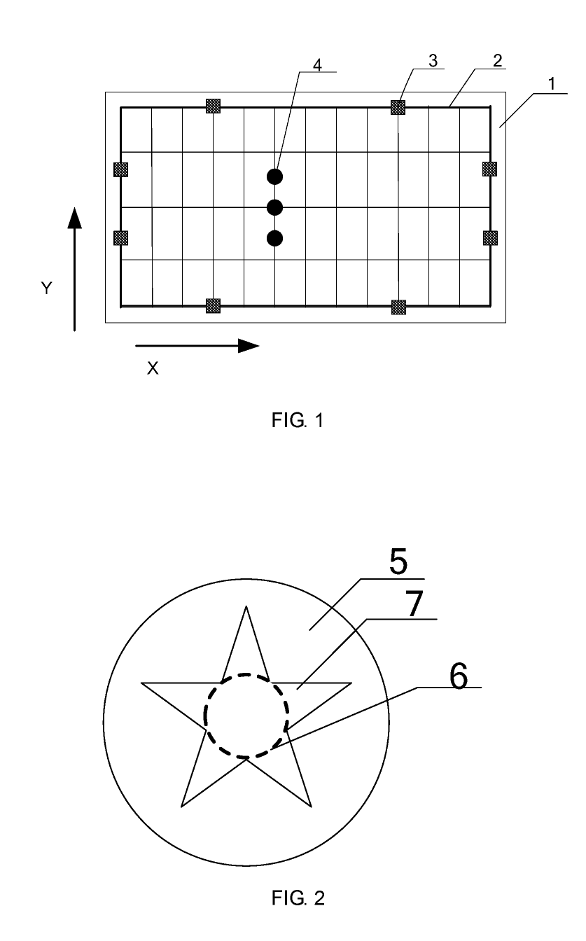

The present invention provides a pin structure and a vacuum apparatus. FIG. 1 shows one embodiment according to the pin structure of the present invention.

As shown in FIG. 1, which is a structure diagram of a pin structure according to the embodiment, comprising a machine 1, and inner pins 4, outer pins 3 located on the machine 1, and the outer pins 3 are located and fixed at edges of the machine 1, and the inner pins 4 are movably located in a middle area of the machine 1, and the inner pins 4 are located on the machine 1 corresponding to a cutting area of a glass substrate 4.

In this embodiment, an amount of the inner pins 4 is three, which are aligned with spaces. The spaces among the inner pins 4 can be determined according to actual cutting sizes. In the three inner pins 4, the spaces between adjacent inner pins 4 are equal or unequal, and no restriction is claimed here. Preferably, all the spaces between adjacent inner pins 4 are equal.

In this embodiment, the outer pins 3 are fixed and located on the surface of the machine 1. The heights and the positions of the outer pins 3 are determined. Because the inner pins 4 are movably located on the machine 1, the positions and heights of the inner pins 4 can be selected according to the actual product size and requirement. Herein, the heights of the inner pins 4 refer to distances from the top of the inner pins 4 to the machine 1. The heights of the outer pins 3 refer to the distances from the top of the outer pins 3 to the machine 1.

When the heights of the inner pins 4 are fixed, the heights of the inner pins 4 should not be less than the heights of the outer pins 3. Then, bottoms of the inner pins 4 comprise engaging elements, and the machine 1 comprises through holes corresponding to the positions of the inner pins 4. The through holes comprise slots engaged with the engaging elements, and the inner pins 4 are inserted in the through holes to be engaged and fixed with the slots with the engaging elements.

When the heights of the inner pins 4 are adjustable, the heights of the inner pins 4 can be smaller than the heights of the inner pins 3. The machine 1 comprises elevating mechanisms 5 corresponding to the positions of the inner pins 4. The distances of the tops of the inner pins 4 to the machine 1 are larger than the heights of the outer pins 3.

The elevating mechanisms comprise inner thread structures. The bottoms of the inner pins 4 comprise outer thread structures, and the inner thread structures and the outer thread structures adapt. When it is required to adjust the heights of the inner pins 4, the inner pins 4 can be controlled to process the depths of the elevating mechanisms for the achievement. Because the thread fixture is prior art. The repeated description is omitted here.

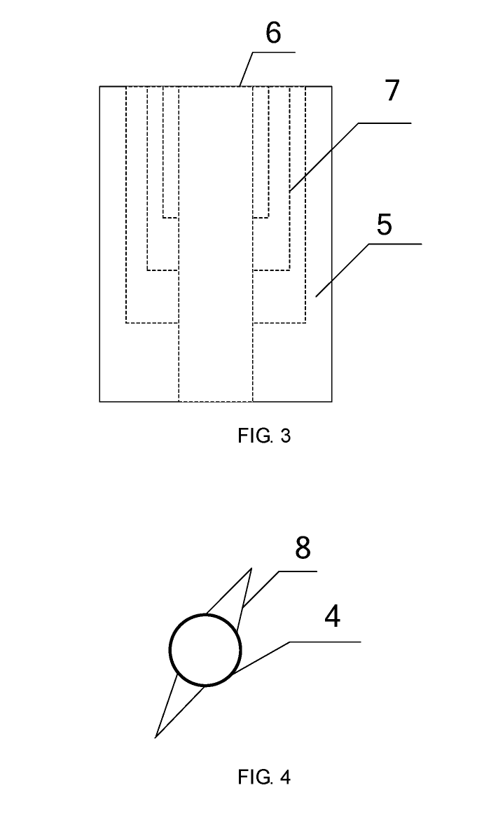

In another embodiment, as shown from FIG. 2 to FIG. 4, the inner pins 4 are cylinders. The elevating mechanisms 5 are cylinders, and middle parts thereof comprise holes 6. The hole diameters of the holes 6 are slightly larger than diameters of the inner pins 4, and at least two slot pairs 7 are provided at the holes 6 along a lateral wall direction of the elevating mechanisms 5, and the slot pair 7 comprises two slots symmetrically located relative to a center of the hole 6 (i.e. the center is the middle point of the longest line of the two slots), and depths of the two slots are identical, and depths of the all slot pairs 7 are different, and outer walls of one ends of the inner pins 4 which contact with the elevating mechanisms 5 comprise pairs of bulges 8, and the pair of bulges 8 comprises two bulges symmetrically located relative to an axis of the inner pin 4 (i.e. the axis is the middle point of the longest line of the two bulges), and the bulges 8 can match with the slot pair 7 (as shown in FIG. 2 and FIG. 4) or cannot match as long as the slot 7 can lock the bulge 8. No restriction is claimed here. When it is required to adjust the heights of the inner pins 4, the inner pin 4 can be inserted into the corresponding slot 7 on demand to achieve the adjustment of the height of the inner pin 4. When it is required to adjust the heights of the inner pins 4, only the inner pin 4 is inserted into the corresponding slot 7 for achievement. Specifically, the structure of the inner pin 4 and the elevating mechanism 5 shown in FIGS. 2-4 is the preferred embodiment, which is illustrated for better understanding. Other structures or other shapes also can be illustrated, and no restriction is claimed here. From the hole 6 shown in FIG. 2 and FIG. 3, the complete hole 6 cannot be observed in practical but communicates with the slot pair 7. For explanation for better understanding, the property is stated here; besides, the amount and side of the slot pairs 7 can determined according to actual demands. No restriction is claimed here.

In this embodiment, the outer pins 3 are distributed on periphery (i.e. the four edges) of the machine 1. As shown in FIG. 1, at least two outer pins 3 are located at the edge in each direction. The amount of the outer pins 3 can be determined on actual demands. No restriction is claimed here.

In this embodiment, as shown in FIG. 1, the inner pins 3 are distributed in the middle area of the machine 1, and the amount of the inner pins 4 is three, which can be located along X direction cutting area or Y direction cutting area on actual demands. The spaces among the inner pins 4 can be set according to the actual product size, and no restriction is claimed here. All the inner pins 4 are located in the cutting area of the glass substrate, and thus, no scratch occurs to the pixel area on the sub panel after cutting the mother panel to promote the product reliability.

Preferably, all the tops of the inner pins 4 and the outer pins 3 comprise metal heads (not shown in figure), and the inner pins 4 and the outer pins 3 provide support function to the glass substrate 2. The positions of the inner pins 4 can be distributed and the amount, the positions of the outer pins 3 can be selected according to the product size to make the support of the inner pins 4 and the outer pins 3 for raising up the glass substrate 2 can satisfy the mechanical requirement and ensure the stability of the glass substrate 2; besides, the contact positions of the inner pins 4 with the glass substrate 2 are all in the cutting area, no damage occurs to the display structure for ensuring the product quality even the electrostatic induction generates between the inner pins 4 and the glass substrate 2.

In this embodiment, in the provided pin structure of the glass substrate, by locating three inner pins in the middle area of the machine, and that the inner pins are movable and the heights are adjustable, the positions and the heights of the inner pins can be determined according to products of various product lines for adapting the glass substrates of various sizes to promote the utility of the pin structure. Besides, the inner pins are located in the cutting area of the glass substrate, and thus, no damage occurs to the pixel structures due to the electrostatic induction even the electrostatic induction generates to ensure the quality of the product. Because the amount of the pins is merely three to reduce the cost, and the possibility of generating electrostatic induction can be decreased in a certain level to promote the reliability of the products.

The present invention further provides a vacuum apparatus, and the vacuum apparatus comprises a reaction chamber, and the reaction chamber comprises the pin structure employed to support the glass substrate which is positioned inside. The specific structure of the pin structure and the technical result brought thereby are described as mentioned in the aforesaid embodiment. The repeated description is omitted here.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

1. A pin structure, comprising a machine, and the machine comprises outer pins and inner pins, the outer pins are located at edges of the machine, and the inner pins are movably located in a middle area of the machine, and an amount of the inner pins is three, which are aligned with spaces corresponding to a cutting area of a glass substrate, and tops of the inner pins and the outer pins comprise metal heads.

2. The pin structure according to claim 1, wherein heights of all the inner pins are adjustable.

3. The pin structure according to claim 1, wherein spaces between any adjacent inner pins are equal.

4. The pin structure according to claim 3, wherein heights of all the inner pins are adjustable.

5. The pin structure according to claim 1, wherein heights of the outer pins are smaller than heights of the inner pins.

6. The pin structure according to claim 5, wherein heights of all the inner pins are adjustable.

7. The pin structure according to claim 5, wherein a surface of the machine further comprises through holes corresponding to the inner pins to be inserted and fixed; bottoms of the inner pins comprise engaging elements, and the through holes comprise slots engaged with the engaging elements.

8. The pin structure according to claim 7, wherein heights of all the inner pins are adjustable.

9. The pin structure according to claim 1, wherein heights of the inner pins are smaller than heights of the outer pins, and the machine comprises elevating mechanisms for inserting and fixing the inner pins, and the elevating mechanisms are employed to adjust distances from the inner pins to the machine, and distances of the tops of the inner pins to the machine are larger than distances of the tops of the outer pins to the machine.

10. The pin structure according to claim 9, wherein the elevating mechanisms comprise inner thread structures, and one ends of the inner pins which contact with the elevating mechanisms comprise outer thread structures, and the inner thread structures and the outer thread structures adapt, and heights of the inner pins are adjusted by rotating the inner pins.

11. The pin structure according to claim 9, wherein both the inner pins and the elevating mechanisms are cylinders, and middle parts of the elevating mechanisms comprise holes, and hole diameters of the holes are slightly larger than diameters of the inner pins, and at least two slot pairs are provided at the holes along a lateral wall direction of the elevating mechanisms, and the slot pair comprises two slots symmetrically located relative to a center of the hole, and depths of the two slots are identical, and depths of the all slot pairs are different, and outer walls of one ends of the inner pins which contact with the elevating mechanisms comprise pairs of bulges, and the pair of bulges comprises two bulges symmetrically located relative to an axis of the inner pin, and the bulges can be embedded in the slot pair.

12. The pin structure according to claim 1, wherein at least two of the outer pins are distributed on four edges of the machine.

13. A vacuum apparatus, comprising a reaction chamber, wherein the reaction chamber comprises the pin structure according to any one of claims 1-12, and the pin structure is employed to support the glass substrate.

14. A vacuum apparatus, comprising a reaction chamber, wherein the reaction chamber comprises the pin structure according to claim 1, and the pin structure is employed to support the glass substrate.
